(19) United States
(12) Patent Application Publication
(10) Pub. No.: US 2017/0077215 A1
(43) Pub. Date: Mar. 16, 2017

(54) ELECTRONIC DEVICE AND METHOD OF MANUFACTURING ELECTRONIC DEVICE

(71) Applicant: KABUSHIKI KAISHA TOSHIBA, Tokyo (JP)

(72) Inventor: Hitomi YAMAGUCHI, Yokohama Kanagawa (JP)

(73) Assignee: KABUSHIKI KAISHA TOSHIBA, Tokyo (JP)

(21) Appl. No.: 15/068,495

(22) Filed: Mar. 11, 2016

(30) Foreign Application Priority Data
Sep. 11, 2015 (JP) 2015-180043

(51) Int. Cl. H01L 49/02; H01G 5/011

(52) U.S. Cl. CPC H01L 28/60; H01G 5/011

(57) ABSTRACT

According to one embodiment, an electronic device includes a first element provided on a semiconductor substrate and used for actual operation, and a second element unit constituted by at least one second element for evaluation provided on the semiconductor substrate, wherein the first element includes a first plate-like portion and a first thin-film portion covering the first plate-like portion and forming a cavity therein, and the second element unit includes a plurality of second plate-like portions having different lengths, and at least one second thin-film portion covering the second plate-like portions and forming a cavity therein.

### CROSS-REFERENCE TO RELATED APPLICATIONS

This application is based upon and claims the benefit of priority from Japanese Patent Application No. 2015-180043, filed Sep. 11, 2015, the entire contents of which are incorporated herein by reference.

### FIELD

Embodiments described herein relate generally to an electronic device and a method of manufacturing the electronic device.

### BACKGROUND

An electronic device comprising a micro-electromechanical systems (MEMS) element such as a variable capacitor formed on a semiconductor substrate is suggested. Since an electrode of the variable capacitor is plate-like, it is important to evaluate and control warpage of the plate-like electrode. For example, variations in the warpage lead to nonuniformity in capacitance of the variable capacitor. In addition, the severe warpage may adversely affect a thin-film portion covering the electrode (plate-like portion) and cause a defect in the MEMS element.

However, it has been difficult to accurately evaluate and control warpage of the plate-like portion.

Therefore, an electronic device capable of accurately evaluating and controlling warpage of the plate-like portion of the MEMS element and a method of manufacturing the electronic device are needed.

### BRIEF DESCRIPTION OF THE DRAWINGS

FIG. 1 is an illustration schematically showing a concept of an electronic device of a first embodiment.

FIG. 2 is a cross-sectional view schematically and mainly showing a structure of a second MEMS element of the electronic device of the first embodiment.

FIG. 3 is a plan view schematically and mainly showing the structure of the second MEMS element of the electronic device of the first embodiment.

FIG. 4 is a plan view schematically and mainly showing a structure of a second MEMS element unit of the electronic device of the first embodiment.

FIG. 5 is a cross-sectional view schematically and mainly showing a structure of a first MEMS element of the electronic device of the first embodiment.

FIG. 6 is an illustration schematically showing a relationship between a semiconductor wafer, shot regions and chip regions in the first embodiment.

FIG. 7 is a cross-sectional view schematically showing a part of a method of manufacturing the electronic device of the first embodiment.

FIG. 8 is a cross-sectional view schematically showing a part of the method of manufacturing the electronic device of the first embodiment.

FIG. 9 is a cross-sectional view schematically showing a part of the method of manufacturing the electronic device of the first embodiment.

FIG. 10 is a cross-sectional view schematically showing a part of the method of manufacturing the electronic device of the first embodiment.

FIG. 11 is a flowchart showing a method of evaluating warpage of an electrode in the first embodiment.

FIG. 12 is an illustration schematically showing evaluated portions on the semiconductor wafer in the first embodiment.

FIG. 13 is a graph showing an example of defect rates of the second MEMS elements in the first embodiment.

FIG. 14 is a plan view schematically and mainly showing a structure of a modified example of the second MEMS element unit of the electronic device of the first embodiment.

FIG. 15 is an illustration schematically showing a relationship between a semiconductor wafer, shot regions and chip regions in a second embodiment.

FIG. 16 is an illustration schematically showing a concept of an electronic device of a third embodiment.

FIG. 17 is a plan view schematically and mainly showing a structure of a second MEMS element unit of the electronic device of the third embodiment.

### DETAILED DESCRIPTION

In general, according to one embodiment, an electronic device includes: a first element provided on a semiconductor substrate and used for actual operation; and a second element unit constituted by at least one second element for evaluation provided on the semiconductor substrate, wherein the first element includes a first plate-like portion and a first thin-film portion covering the first plate-like portion and forming a cavity therein, and the second element unit includes a plurality of second plate-like portions having different lengths, and at least one second thin-film portion covering the second plate-like portions and forming a cavity therein.

Various embodiments will be described hereinafter with reference to the accompanying drawings.

### Embodiment 1

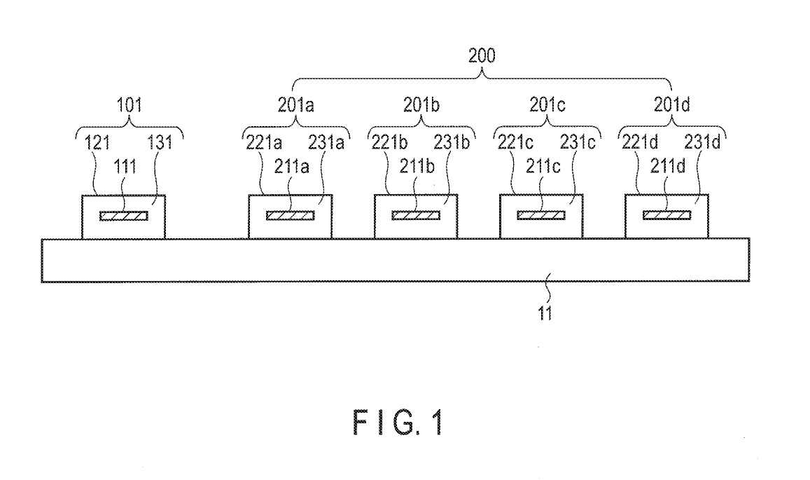

FIG. 1 is an illustration schematically showing a concept of an electronic device of a first embodiment.

In the electronic device of the present embodiment, a first MEMS element 101 and a second MEMS element unit 200 constituted by at least one second MEMS element 201 (in the example of FIG. 1, four second MEMS elements 201a, 201b, 201c and 201d) are provided on the same semiconductor substrate 11. In other words, the first MEMS element 101 and the second MEMS element unit 200 are provided in the same integrated circuit (IC) chip in the present embodiment.

The first MEMS element 101 is used for actual operation. That is, the first MEMS element 101 is a movable element and is actually used as a functional element. In the present embodiment, the first MEMS element 101 is used as a variable capacitor.

The first MEMS element 101 includes a first plate-like portion 111 and a first thin-film portion (first thin-film dome portion) 121 covering the first plate-like portion 111 and forming a cavity 131 therein. The first plate-like portion 111 functions as an electrode of the variable capacitor.

The second MEMS element 201 is used for evaluation. That is, the first MEMS element 101 can be evaluated by evaluating the second MEMS element 201. This will be described later in detail.

The second MEMS element unit 200 includes second plate-like portions 211 (211a, 211b, 211c and 211d) having different lengths, and at least one second thin-film portion (second thin-film dome portion) 221 (221a, 221b, 221c and 221d) covering the second plate-like portions 211 and forming a cavity 231 (231a, 231b, 231c and 231d) therein. In the example of FIG. 1, the second MEMS element unit 200 is constituted by four second MEMS elements 201a, 201b, 201c and 201d. The second MEMS elements 201 (201a, 201b, 201c and 201d) include second plate-like portions 211 (in the example of FIG. 1, four second plate-like portions 211a, 211b, 211c and 211d) and second thin-film portions 221 (in the example of FIG. 1, four second thin-film portions 221a, 221b, 221c and 221d) covering the second plate-like portions 211, respectively. That is, in the present embodiment, one second MEMS element 201 is constituted by one second plate-like portion 211 and one second thin-film portion 221.

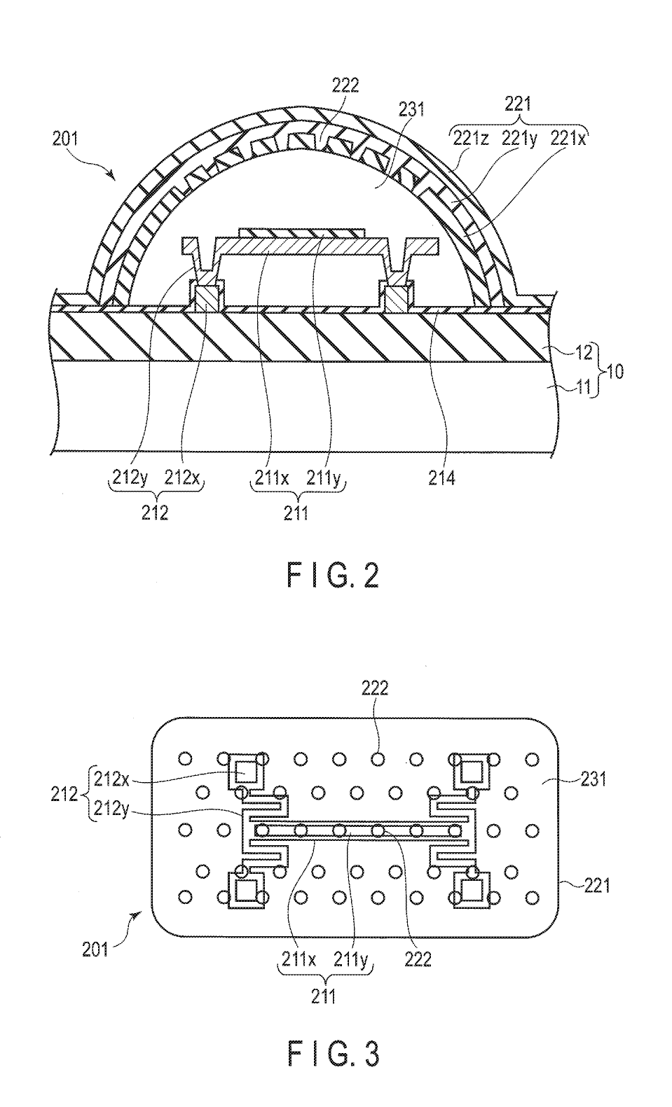

FIG. 2 is a cross-sectional view schematically and mainly showing a structure of the second MEMS element 201 of the electronic device of the present embodiment. FIG. 3 is a plan view schematically and mainly showing the structure of the second MEMS element 201 of the electronic device of the present embodiment. The second MEMS element 201 shown in FIG. 2 and FIG. 3 corresponds to an arbitrary one of the second MEMS elements 201a, 201b, 201c and 201d shown in FIG. 1.

The second MEMS element 201 is provided on an underlying region 10 including a semiconductor substrate 11 and an interlayer insulating film 12. The second MEMS element 201 includes an electrode portion 211 corresponding to the second plate-like portion, supporting portions 212 supporting the electrode portion 211, and a second thin-film portion 221. A cavity 231 is formed inside the second thin-film portion 221. An insulating film 214 is formed on the interlayer insulating film 12.

The electrode portion 211 has a structure in which material layers formed of different materials are stacked. More specifically, the electrode portion 211 is constituted by a first material layer 211x formed of metal (for example, AlCu) and a second material layer 211y formed of an insulator (for example, silicon nitride [SiN]). A principal surface of the electrode portion 211 is substantially parallel to a principal surface of the semiconductor substrate 11. However, the electrode portion 211 is actually warped by a stress difference between the first material layer 211x and the second material layer 211y. More specifically, the electrode portion 211 is warped such that the central part of the electrode portion 211 is away from the principal surface of the semiconductor substrate 11. The warpage will be described later in detail.

The supporting portions 212 fix the ends of the electrode portion 211. Each supporting portion 212 is constituted by a lower portion 212x formed on the interlayer insulating film 12 and an upper portion 212y formed on the lower portion 212x and connected to the electrode portion 211.

The second thin-film portion 221 functions as a protective film, and is constituted by a first layer 221x, a second layer 221y formed on the first layer 221x and a third layer 221z formed on the second layer 221y. The first layer 221x is formed of, for example, silicon oxide (SiO), and comprises holes 222 in a region above the second plate-like portion 211. The second layer 221y is formed of, for example, resin, and fills the holes 222. The third layer 221z is formed of, for example, silicon nitride (SiN).

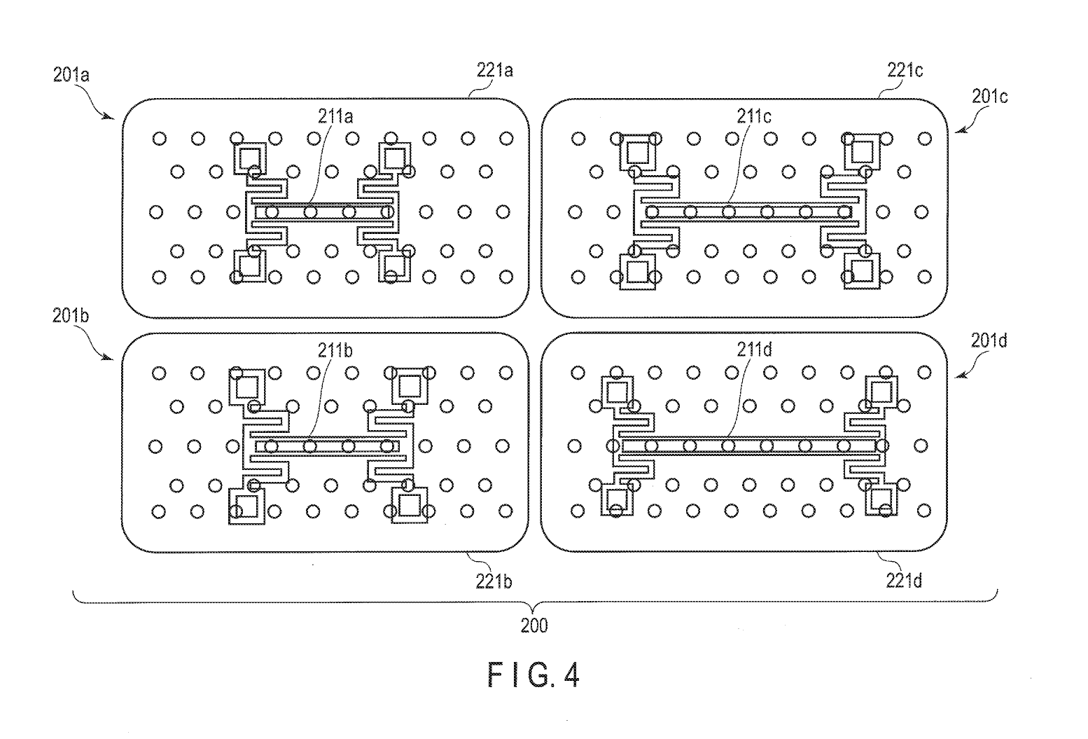

FIG. 4 is a plan view schematically and mainly showing a structure of the second MEMS element unit 200 of the electronic device of the present embodiment.

As described above, the second MEMS element unit 200 is constituted by the second MEMS elements 201a, 201b, 201c and 201d. The specific structure of each of the second MEMS elements 201a, 201b, 201c and 201d has been described with reference to FIG. 2 and FIG. 3.

As shown in FIG. 4, the electrode portions (second plate-like portions) 211a, 211b, 211c and 211d included in the second MEMS elements 201a, 201b, 201c and 201d, respectively, have different lengths. For example, the lengths of the electrode portions 211a, 211b, 211c and 211d are 175, 200, 225 and 250 μm, respectively. The layout and the number of the second MEMS elements 201a, 201b, 201c and 201d may be arbitrarily changed.

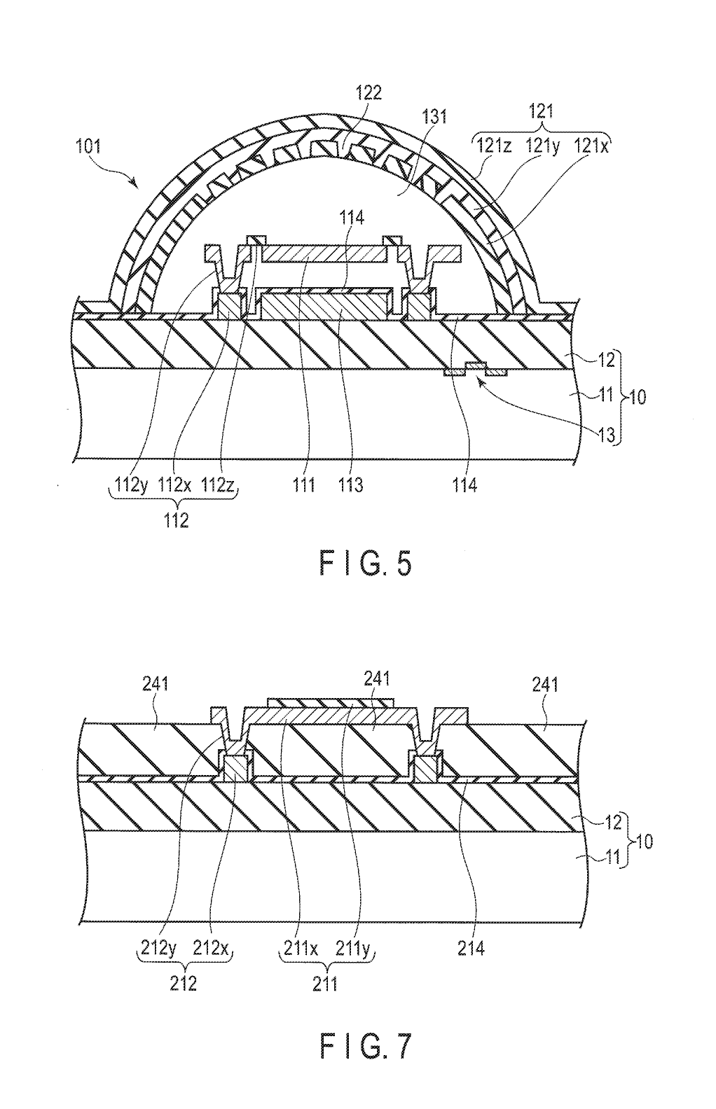

FIG. 5 is a cross-sectional view schematically and mainly showing a structure of the first MEMS element 101 of the electronic device of the present embodiment. The first MEMS element 101 shown in FIG. 5 corresponds to the first MEMS element 101 shown in FIG. 1.

The first MEMS element 101 is provided on the underlying region 10 including the semiconductor substrate 11, the interlayer insulating film 12 and a transistor 13. The first MEMS element 101 is provided on the semiconductor substrate 11 on which the second MEMS elements 201 are also provided. The first MEMS element 101 includes a top electrode 111 corresponding to the first plate-like portion, supporting portions 112 supporting the top electrode 111, a bottom electrode 113 provided under the top electrode 111 and a first thin-film portion 121. A cavity 131 is formed inside the first thin-film portion 121. An insulating film 114 is formed on the interlayer insulating film 12.

The top electrode 111 functions as one electrode of the variable capacitor, and is movable in a direction perpendicular to the principal surface of the semiconductor substrate 11. The top electrode 111 is formed of the same material (for example, metal such as AlCu) and in the same process as the first material layer 211x of the electrode portion 211 of the second MEMS element 201. A principal surface of the top electrode 111 is substantially parallel to the principal surface of the semiconductor substrate 11. The top electrode 111 is actually warped such that the central part of the top electrode 111 is away from the principal surface of the semiconductor substrate 11. Differently from the electrode portion 211 of the second MEMS element 201, however, the top electrode 111 of the first MEMS element 101 does not have a stacked structure. Therefore, the warpage of the top electrode 111 is less than that of the electrode portion 211 of the second MEMS element 201.

The supporting portions 112 fix the ends of the top electrode 111. Each supporting portion 112 is constituted by a lower portion 112x formed on the interlayer insulating film 12, an upper portion 112y formed on the lower portion 112x, and a spring portion 112z provided between the upper portion 112y and the top electrode 111. The spring portion 112z is formed of the same material (for example, insulator such as SiN) and in the same process as the second material layer 211y of the electrode portion 211 of the second MEMS element 201.

The bottom electrode 113 functions as the other electrode of the variable capacitor. The surface of the bottom electrode 113 is covered with the insulating film 114. The insulating film 114 is formed of the same material and in the same process as the insulating film 214 shown in FIG. 2.

The first thin-film portion 121 functions as a protective film, and is constituted by a first layer 121x, a second layer 121y formed on the first layer 121x and a third layer 121z formed on the second layer 121y. The first thin-film portion 121 is formed of the same material and in the same process as the second thin-film portion 221 of the second MEMS element 201. That is, the first layer 121x is formed of, for example, silicon oxide (SiO), and comprises holes 122 in a region above the first plate-like portion 111. The second layer 121y is formed of, for example, resin, and fills the holes 122. The third layer 121z is formed of, for example, silicon nitride (SiN).

As described above, the top electrode 111 is movable in the direction perpendicular to the principal surface of the semiconductor substrate 11, and functions as a movable electrode of the variable capacitor. When a voltage applied between the top electrode 111 and the bottom electrode 113 is changed, the distance between the top electrode 111 and the bottom electrode 113 is changed by electrostatic force and the capacitance of the variable capacitor is also changed.

Next, regions in which the first MEMS elements 101 and the second MEMS element units 200 are formed in the electronic device of the present embodiment are described.

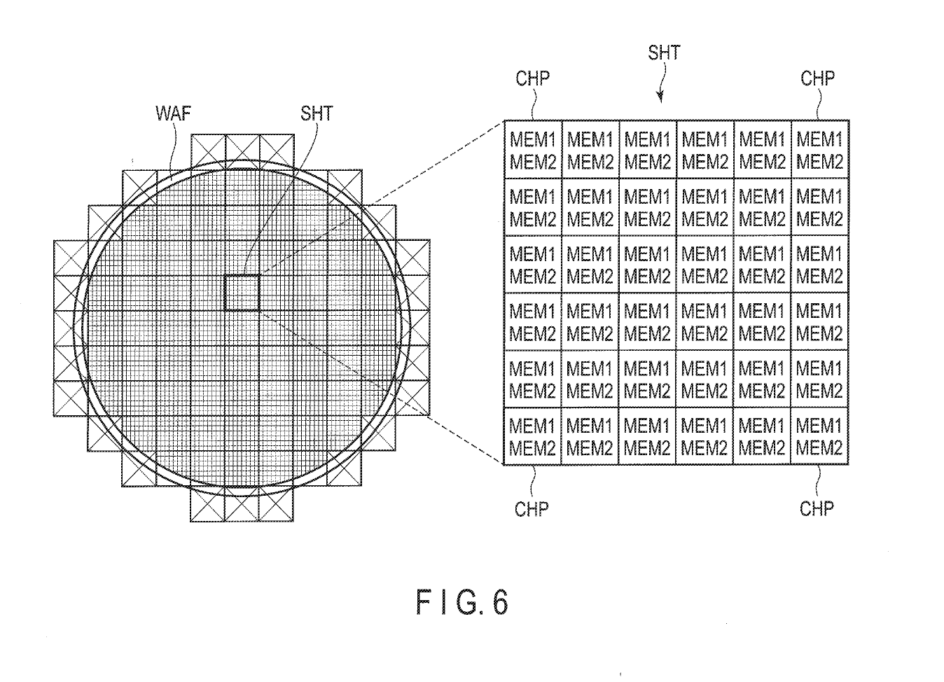

FIG. 6 is an illustration schematically showing a relationship between a semiconductor wafer, shot regions and chip regions.

As shown in FIG. 6, a semiconductor wafer WAF includes shot regions (one-shot regions) SHT. The shot region SHT is a unit of region for which lithography is simultaneously performed in a lithography process such as an exposure process. That is, the shot region SHT corresponds to a region to which a pattern on an exposure mask (reticle, etc.) is simultaneously transferred. Further, each shot region SHT includes chip regions CHP. The chip region CHP is a unit of region constituting a single chip (IC chip).

In the present embodiment, both the first MEMS element (MEM1) and the second MEMS element unit (MEM2) are formed in each chip region CHP as shown in FIG. 6. That is, in the present embodiment, the first MEMS element (MEM1) and the second MEMS element unit (MEM2) are formed in the same chip region CHP. The second MEMS element unit (MEM2) is provided in a test element group (TEG) for quality control.

Next, a method of manufacturing the electronic device of the present embodiment is described.

FIG. 7 to FIG. 10 are cross-sectional views schematically showing the method of manufacturing the electronic device of the present embodiment. FIG. 7 to FIG. 10 mainly shows the manufacturing method in a region in which the second MEMS element 201 is formed.

First, as shown in FIG. 7, a metal film is formed on an underlying region 10 including a semiconductor substrate 11, an interlayer insulating film 12 and a transistor (not shown). Next, lower portions 212x of supporting portions 212 are formed by patterning the metal film. At this time, lower portions 112x of supporting portions 112 and a bottom electrode 113 are formed together in a region in which the first MEMS element 101 shown in FIG. 5 is formed. Then, an insulating film 214 is formed on the entire surface and a sacrificial layer (resin layer) 241 is formed on the insulating film 214. Holes are formed on the lower portions 212x of the supporting portions 212, respectively, by patterning the insulating film 214 and the sacrificial layer 241. Following that, a metal film (AlCu film) is formed on the entire surface. A first material layer 211x of an electrode portion 211 and upper portions 212y of the supporting portions 212 are formed by patterning the metal film. At this time, a top electrode 111 and upper portions 112y of the supporting portions 112 are formed together in the region in which the first MEMS element 101 shown in FIG. 5 is formed. After that, an insulating film (SiN film) is formed on the entire surface. A second material layer 211y of the electrode portion 211 is formed by patterning the insulating film. At this time, spring portions 112z are formed together in the region in which the first MEMS element 101 shown in FIG. 5 is formed.

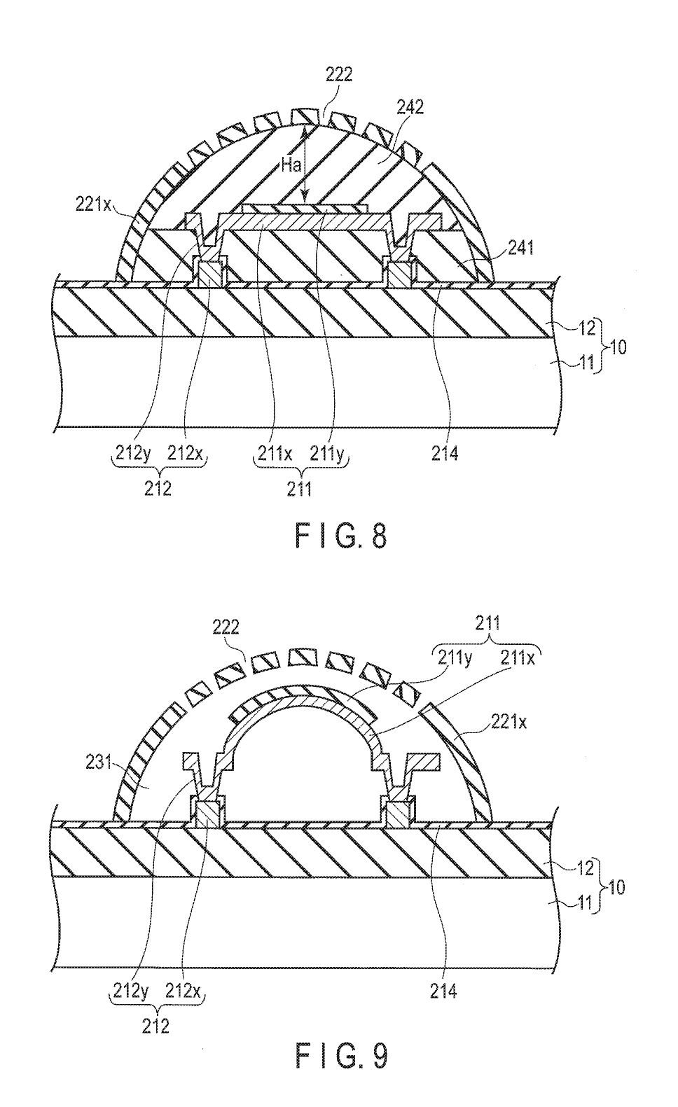

Next, as shown in FIG. 8, a sacrificial layer (resin layer) 242 is formed on the entire surface, and the sacrificial layers 241 and 242 are patterned. Next, a first layer (SiO layer) 221x of a second thin-film portion 221 is formed on the entire surface. Holes 222 are formed by patterning the first layer 221x. At this time, holes 122 are formed together in a first layer 121x of a first thin-film portion 121 in the region in which the first MEMS element 101 shown in FIG. 5 is formed.

Next, as shown in FIG. 9, etching gas is supplied from the holes 222 and the sacrificial layers 241 and 242 are thereby removed. As a result, a cavity 231 is formed inside the first layer 221x. At this time, a cavity 131 is formed together in the region in which the first MEMS element 101 shown in FIG. 5 is formed. By removing the sacrificial layers 241 and 242, the electrode portion 211 is warped such that the central part of the electrode portion 211 is away from the principal surface of the semiconductor wafer 11. In the region in which the first MEMS element 101 is formed, too, the top electrode 111 is warped such that the central part of the top electrode 111 is away from the principal surface of the semiconductor wafer 11. In particular, since the first material layer 211x and the second material layer 211y of the electrode portion 211 are formed of different materials in the region in which the second MEMS element 201 shown in FIG. 9 is formed, the electrode portion 211 is largely warped by a stress difference between the first material layer 211x and the second material layer 211y.

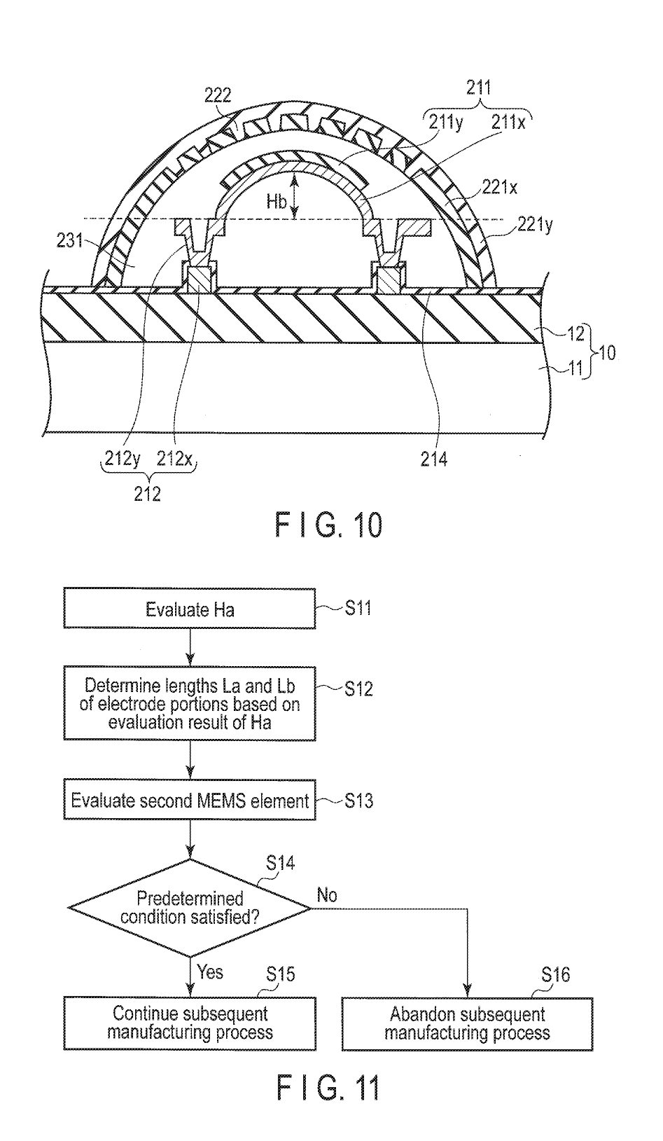

Next, as shown in FIG. 10, a second layer (resin layer) 221y is formed on the first layer 221x of the second thin-film portion 221. The holes 222 are filled with the second layer 221y. At this time, a second layer 121y of the first thin-film portion 121 is formed together and the holes 122 are filled in the region in which the first MEMS element 101 shown in FIG. 5 is formed.

The structure shown in FIG. 2 can be achieved by further forming a third layer (SiN layer) 221z of the second thin-film portion 221 on the second layer 221y. At this time, a third layer 121z of the first thin-film portion 121 is formed together and the structure shown in FIG. 5 can be thereby achieved in the region in which the first MEMS element 101 shown in FIG. 5 is formed.

As described above, the top electrode 111 of the first MEMS element 101 is warped such that the central part of the top electrode 111 is away from the principal surface of the semiconductor wafer 11 during the manufacturing process (more specifically, in the step shown in FIG. 9). Variations in the warpage lead to nonuniformity in capacitance of the variable capacitor. As a result, a variable capacitor having desired characteristics cannot be achieved. In addition, severe warpage may adversely affect the first thin-film portion 121 covering the top electrode 111 and cause a defect in the MEMS element. For example, when forming the second layer (resin layer) 121y on the first layer 121x of the first thin-film portion 121 to fill the holes 122 in the step shown in FIG. 10, there is a possibility that part of the second layer (resin layer) 121y touches the top electrode 111 through the holes 122. Therefore, it is important to evaluates and control the warpage of the top electrode 111.

In order to achieve the above, a second MEMS element unit 200 including second MEMS elements 201 is provided in the present embodiment such that the warpage of the electrode can be accurately evaluated and controlled by the second MEMS element unit 200.

The warpage Hb (FIG. 10) of the electrode portion 211 of the second MEMS element 201 is generally given by:

Hb∝L³×(σₓ−σ_{y})/t³, (1)

where L is the length of the electrode portion 211 (length of the electrode portion 211 between the supporting portions 212), t is the thickness of the electrode portion 211, σₓ is the stress of the first material layer 211x of the electrode portion 211, and σ_{y} is the stress of the second material layer 211y of the electrode portion 211.

Expression (1) shows that the warpage Hb is proportional to L³. Therefore, a second MEMS elements 201 having electrode portions 211 of different lengths L is formed in the present embodiment. The warpage Hb becomes large as the length L becomes large. On the assumption that the thickness of the sacrificial layer 242 is Ha, the electrode portion 211 touches the second thin-film portion 221 when Ha<Hb. Therefore, the warpages of the electrode portions 211 of the second MEMS elements 201 can be evaluated by deciding one of the second MEMS elements 201 in which the electrode portion 211 touches the second thin-film portion 221. Since there is a correlation between the warpages of the electrode portions 211 of the second MEMS elements 201 and the warpage of the top electrode 211 of the first MEMS element 101, the warpage of the top electrode 111 of the first MEMS element 101 can be evaluated and controlled based on the evaluation result of the warpages of the electrode portions 211 of the second MEMS elements 201. This is hereinafter described in detail.

FIG. 11 is a flowchart showing a method of evaluating the warpage of the electrode. In the method shown in FIG. 11, the quality of the first MEMS element 101 is checked based on the evaluation result (quality check) of the warpages of the electrode portions 211 of the second MEMS elements 201. This point is hereinafter described.

As described above, when variable capacitor is manufactured by MEMS technology, an electrode of the variable capacitor is warped. Variations in the warpage lead to nonuniformity in capacitance of the variable capacitor. Therefore, in order to secure the capacitance accuracy of the variable capacitor, the warpage of the top electrode ill of the first MEMS element 101 should preferably be controlled to fall within a certain range. That is, the warpage should not be too great or too small. Since there is a correlation between the warpage of the electrode portions 211 of the second MEMS elements 201 and that of the top electrode 111 of the first MEMS element 101, the quality of the first MEMS element 101 can be determined based on the warpage of the top electrode 111 of the first MEMS element 101 by evaluating the warpage of the electrode portions 211 of the second MEMS elements 201.

If the sacrificial layer 242 is varied by nonuniformity in the process, however, the determination result may be changed even if Hb is constant. It is necessary to evaluate Ha in the previous step and select an appropriate length L of the electrode portion based on expression (1). Therefore, Ha is first evaluated (S11). More specifically, Ha is evaluated by evaluating the thickness of the sacrificial layer 242.

Next, lengths La and Lb of electrode portions are determined based on the evaluation result of Ha (S12). More specifically, length conditions La and Lb of the electrode portions of the second MEMS element unit 200 are determined in order to determine a necessary condition for determining whether the warpage of the top electrode 111 of the first MEMS element 101 falls within the certain range.

For example, it is hereinafter assumed that a second MEMS element unit 200 is constituted by five second MEMS elements 201 having electrode lengths L1, L2, L3, L4 and L5 (L1<L2<L3<L4<L5). In this example, it is assumed that L3 and L4 are determined as La and Lb in step S12 based on the evaluation result in step S11.

Next, the second MEMS elements 201 are evaluated (S13). More specifically, an optical observation on a portion having electrode length L3 and a portion having electrode length L4 is carried out in several regions in the semiconductor wafer.

Next, whether a predetermined condition is satisfied is determined (S14). More specifically, whether the defect rate of a second MEMS element 201 having an electrode portion 211 of length L3 is less than or equal to 10% and the defect rate of a second MEMS element 201 having an electrode portion 211 of length L4 is greater than or equal to 90% is determined.

If the determination result is Yes in S14, it is considered that the second MEMS elements 201 satisfying the condition are appropriate, and the first MEMS element 101 formed on the semiconductor wafer on which the second MEMS elements 201 satisfying the condition are formed is also appropriate. In this case, the subsequent manufacturing process is executed and the product is brought to perfection (S15).

If the determination result is No in S14, the subsequent manufacturing process is not executed (S16).

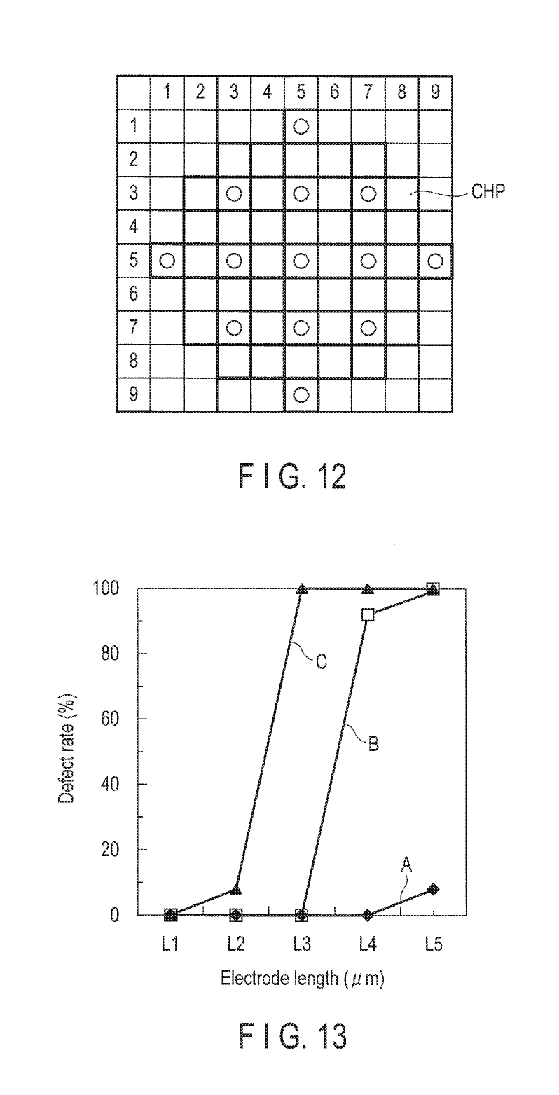

FIG. 12 is an illustration schematically showing evaluated portions on the semiconductor wafer. Chip regions CHP marked with circles are chip regions to be evaluated (portions to be evaluated). As shown in FIG. 12, it is not necessary to evaluate all the chip regions CHP on the semiconductor wafer.

For example, when the electrode portion 211 is warped and thus touches the second thin-film portion 221, an abnormality of the second thin-film portion 221 caused by the touch is observed. A second MEMS element 201 in which such an abnormality is observed is considered as defective. Based on such observation by an optical microscope, the defect rate of each of five types of second MEMS elements 201 having electrode lengths L1, L2, L3, L4 and L5 is calculated.

FIG. 13 is a graph showing an example of defect rates of second MEMS elements formed in different lots (in this example, lots A, B and C). It is assumed that L3 and L4 are selected as La and Lb in all lots A, B and C. In lot C, the defect rate of a second MEMS element 201 having electrode length L3 is 100%. Therefore, lot C does not satisfy the condition of S14 since the warpage is too great. In lot B, the defect rate of a second MEMS element 201 having electrode length L3 is 0%, and the defect rate of a second MEMS element 201 having electrode length L4 is greater than 90%. Therefore, lot B satisfies the condition of S14 since the warpages are appropriate. In lot A, the defect rate of a second MEMS element 201 having electrode length L4 is 0%. Therefore, lot A does not satisfy the condition of S14 since the warpage is too small.

As described above, in the present embodiment, a second MEMS element unit 200 including second plate-like portions (electrode portions) 211 having different lengths is provided on a semiconductor wafer on which a first MEMS element 101 used for actual operation is provided. Therefore, the warpage of the first MEMS element 101 can be accurately evaluated and controlled based on the evaluation result of the warpage of the second plate-like portions 211 (for example, the evaluation result of defect rates of the second MEMS elements 201 based on warpage of the second plate-like portions 211). As a result, a first MEMS element 101 having desired characteristics can be efficiently achieved.

Since the quality of the second thin-film portion 221 affected by warpage of the second plate-like portion (electrode portion) 211 can be evaluated, the height of the second thin-film portion 221 (height from the second plate-like portion [electrode portion] 211) can also be evaluated.

The second MEMS element 201 can be easily evaluated by observation of shape by means of, for example, an optical microscope.

Since the evaluation can be executed when the second plate-like portion 211 is warped, the appropriate evaluation can be executed even if the first MEMS element 101 and the second MEMS elements 201 are not completely manufactured.

In the present embodiment, since each second MEMS element 201 is constituted by a second plate-like portion (electrode portion) 211 and a second thin-film portion 221, a similar structure to the first MEMS element 101 can be realized by each second MEMS element 201. Therefore, a correct evaluation can be executed by using the second MEMS elements 201.

In the present embodiment, the holes 222 are provided in the first layer 221x of the second thin-film portion 221 above the second plate-like portion 211. Accordingly, a situation that the second layer 221y (for example, resin layer) formed on the first layer 221x touches the second plate-like portion 211 through the holes 222 can be efficiently realized. Therefore, a defect mode caused by such a situation can be efficiently realized.

In the present embodiment, the first MEMS element and the second MEMS elements are formed in the same chip region CHP as shown in, for example, FIG. 6. Therefore, the second MEMS elements can be formed in a similar environment to the first MEMS element. Therefore, the first MEMS element 101 can be accurately evaluated by using the second MEMS elements 201.

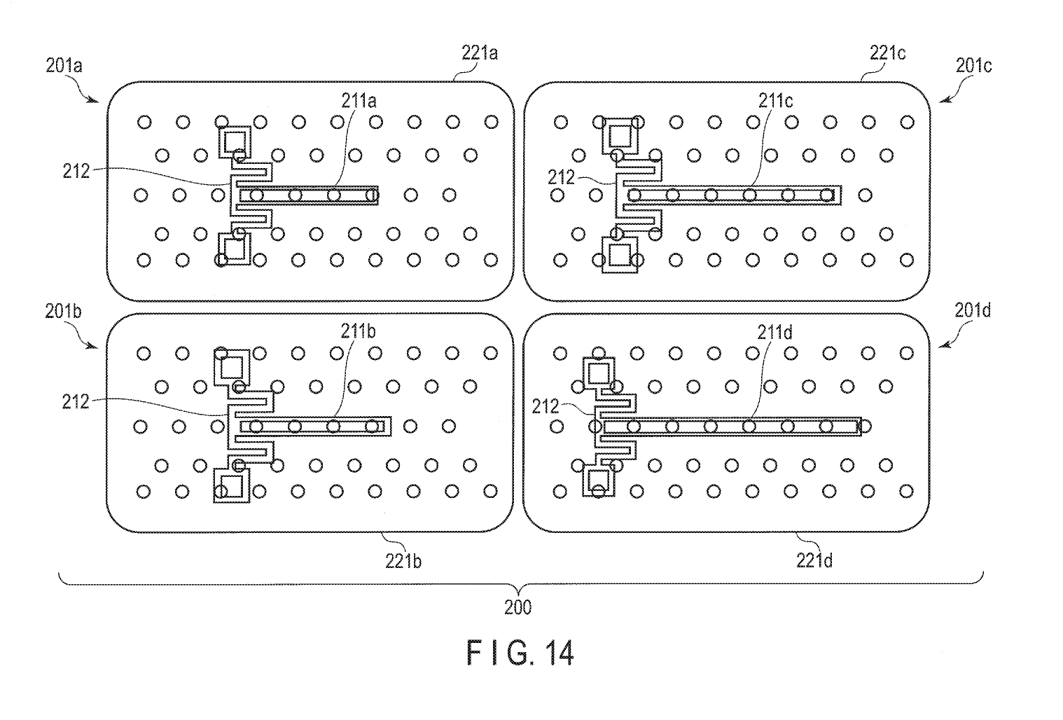

FIG. 14 is a plan view schematically and mainly showing a structure of a modified example of the second MEMS element unit 200 of the electronic device of the present embodiment.

In the above-described embodiment, supporting portions 212 are provided at both ends of the second plate-like portion (electrode portion) 211 as shown in FIG. 2, FIG. 3 and FIG. 4. In this modified example, however, a supporting portion 212 is provided at only one end of the second plate-like portion (electrode portion) 211.

The same effect as the above-described embodiment can be achieved in this modified example.

### Embodiment 2

Next, a second embodiment is described. Since the basic matters are similar to those of the first embodiment, the description of the matters described in the first embodiment is omitted.

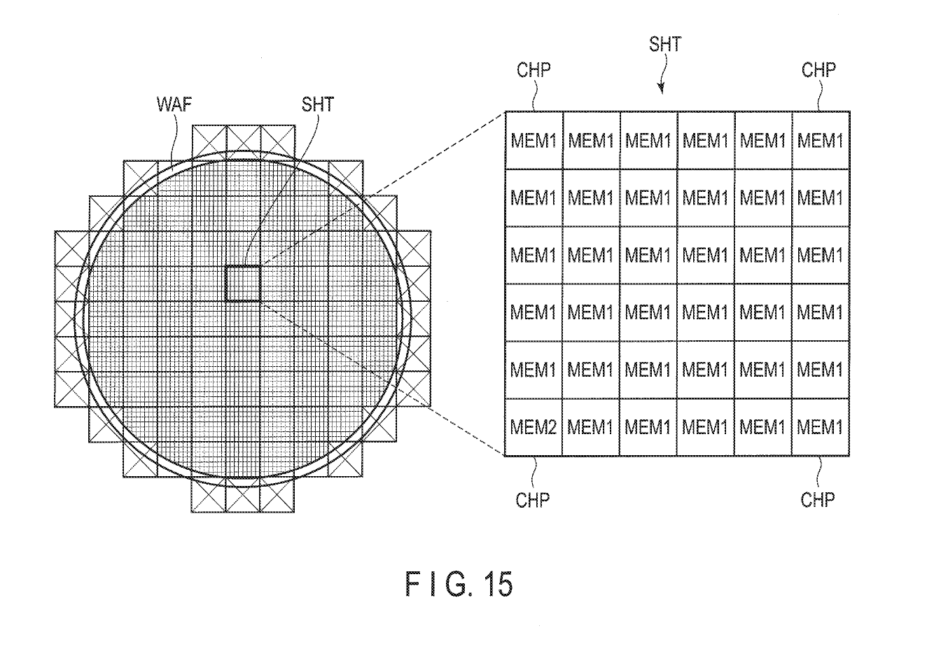

FIG. 15 is an illustration schematically showing a relationship between a semiconductor wafer, shot regions and chip regions in the present embodiment.

In a similar way to FIG. 6 of the first embodiment, one semiconductor wafer WAF includes shot regions (one-shot regions) SHT. Further, each shot region SHT includes chip regions CHP.

As shown in FIG. 15, a first MEMS element (MEM1) and a second MEMS element unit (MEM2) are formed in different chip regions CHP in the present embodiment. In the example shown in FIG. 15, in each shot region SHT, a TEG for quality control including a second MEMS element unit (MEM2) is provided but a first MEMS element (MEM1) is not provided in one chip region CHP (lower left chip region CHP). In each of the other chip regions CHP, a first MEMS element (MEM1) is provided but a second MEMS element unit (MEM2) is not provided.

In the present embodiment, too, a second MEMS element unit 200 including second plate-like portions (electrode portions) 211 having different lengths is provided on a semiconductor wafer on which a first MEMS element 101 used for actual operation is provided, in a similar way to the first embodiment. Therefore, the same basic effect as the first embodiment can be achieved in the present embodiment.

In the present embodiment, no second MEMS element unit 200 is formed in a chip region CHP in which a first MEMS element (MEM1) used for actual operation is provided. Therefore, the area of chip regions CHP in which first MEMS elements (MEM1) are formed can be reduced.

### Embodiment 3

Next, a third embodiment is described. Since the basic matters are similar to those of the first and second embodiments, the description of the matters described in the first and second embodiments is omitted.

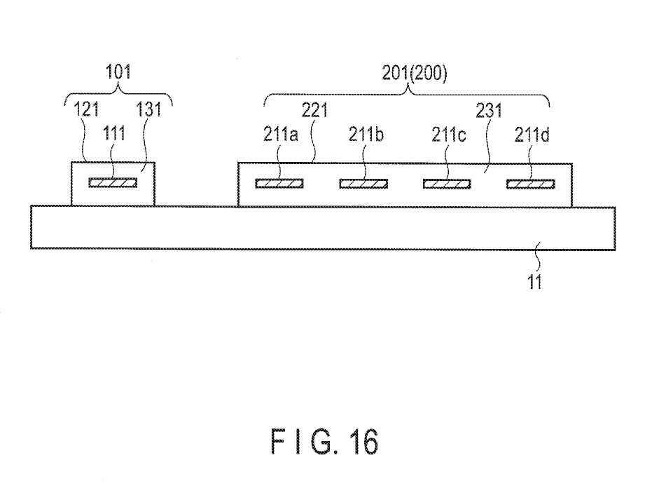

FIG. 16 is an illustration schematically showing a concept of an electronic device of the third embodiment.

The electronic device of the present embodiment is basically the same as the first embodiment. A first MEMS element 101 and a second MEMS element unit 200 constituted by at least one second MEMS element 201 are provided on the same semiconductor substrate 11. That is, the first MEMS element 101 and the second MEMS element unit 200 are provided in the same integrated circuit (IC) chip in the present embodiment, in a similar way to the first embodiment.

In the present embodiment, too, the second MEMS element unit 200 comprises second plate-like portions 211 (211a, 211b, 211c and 211d) having different lengths. In the present embodiment, however, the second plate-like portions 211 (211a, 211b, 211c and 211d) are covered with a single second thin-film portion 221. That is, in the present embodiment, one second MEMS element 201 is constituted by second plate-like portions 211 and one second thin-film portion 221. Accordingly, the second MEMS element unit 200 is constituted by a single second MEMS element 201 in the present embodiment.

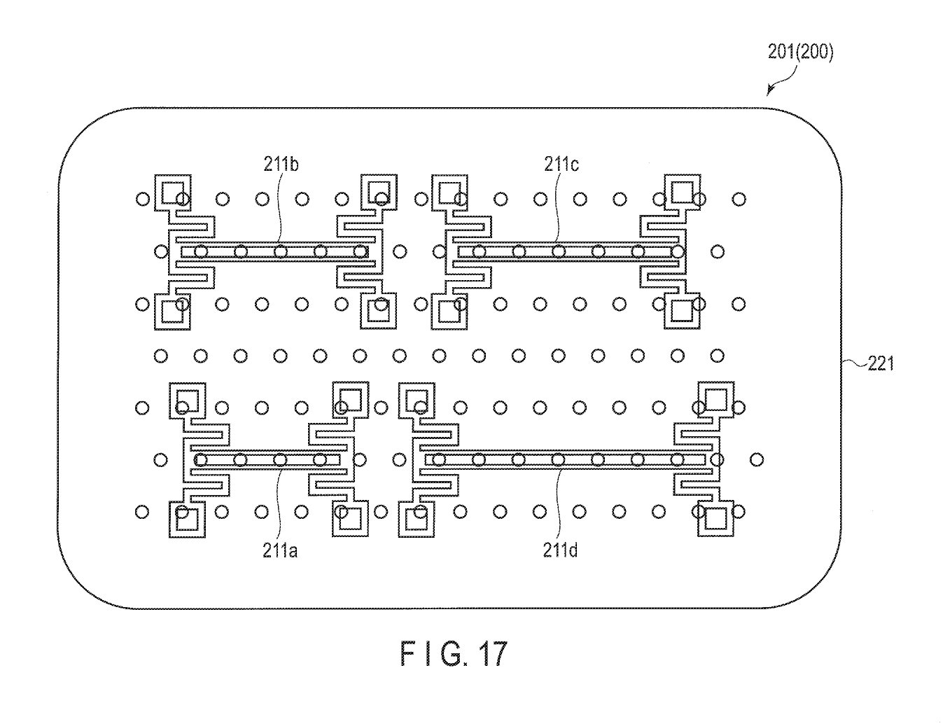

FIG. 17 is a plan view schematically and mainly showing a structure of the second MEMS element unit 200 of the electronic device of the present embodiment.

As described above, the second MEMS element unit 200 (second MEMS element 201) includes second plate-like portions (electrode portion) 211a, 211b, 211c and 211d having different lengths and a single second thin-film portion 221. For example, the lengths of the second plate-like portions (electrode portions) 211a, 211b, 211c and 211d are 175 μm, 200 μm, 225 μm and 250 μm, respectively. The layout and the number of the second plate-like portions (electrode portions) 211a, 211b, 211c and 211d may be arbitrarily changed.

In the present embodiment, too, a second MEMS element unit 200 including second plate-like portions (electrode portions) 211 having different lengths is provided on a semiconductor wafer on which a first MEMS element 101 used for actual operation is provided, in a similar way to the first embodiment. Therefore, the same basic effect as the first embodiment can be achieved in the present embodiment.

In the present embodiment, the second MEMS element unit 200 is constituted by a single second MEMS element 201, and the second plate-like portions (electrode portions) 211 are covered with the single second thin-film portion 221. Therefore, the area of the entire second MEMS element unit 200 can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a first element provided on a semiconductor substrate and used for actual operation; and
a second element unit constituted by at least one second element for evaluation provided on the semiconductor substrate,
wherein the first element includes a first plate-like portion and a first thin-film portion covering the first plate-like portion and forming a cavity therein, and
the second element unit includes a plurality of second plate-like portions having different lengths, and at least one second thin-film portion covering the second plate-like portions and forming a cavity therein.

2. The electronic device of claim 1, wherein
the second element unit is constituted by a plurality of second elements, and
the at least one second thin-film portion is a plurality of second thin-film portions covering the second plate-like portions, respectively.

3. The electronic device of claim 2, wherein
each of the second thin-film portions includes a first layer having a hole above corresponding one of the second plate-like portions, and a second layer provided on the first layer and filling the hole.

4. The electronic device of claim 1, wherein
the second element unit is constituted by a single second element, and
the at least one second thin-film portion is a single second thin-film portion covering the second plate-like portions.

5. The electronic device of claim 4, wherein
the single second thin-film portion includes a first layer having holes above the second plate-like portions, respectively, and a second layer provided on the first layer and filling the holes.

6. The electronic device of claim 1, wherein
each of the second plate-like portions has a structure in which a plurality of material layers formed of different materials are stacked.

7. The electronic device of claim 1, wherein
each of the second plate-like portions is warped such that a central part of each of the second plate-like portions is away from a principal surface of the semiconductor substrate.

8. The electronic device of claim 1, wherein
the first plate-like portion is movable in a direction perpendicular to a principal surface of the semiconductor substrate.

9. The electronic device of claim 1, wherein
the first plate-like portion functions as an electrode of a variable capacitor.

10. A method of manufacturing an electronic device, the method comprising forming, on a same semiconductor wafer, a first element used for actual operation and a second element unit constituted by at least one second element for evaluation,
wherein the first element includes a first plate-like portion and a first thin-film portion covering the first plate-like portion and forming a cavity therein, and
the second element unit includes a plurality of second plate-like portions having different lengths, and at least one second thin-film portion covering the second plate-like portions and forming a cavity therein.

11. The method of claim 10, wherein
the second element unit is constituted by a plurality of second elements, and
the at least one second thin-film portion is a plurality of second thin-film portions covering the second plate-like portions, respectively.

12. The method of claim 11, wherein
each of the second thin-film portions includes a first layer having a hole above corresponding one of the second plate-like portions, and a second layer provided on the first layer and filling the hole.

13. The method of claim 10, wherein
the second element unit is constituted by a single second element, and
the at least one second thin-film portion is a single second thin-film portion covering the second plate-like portions.

14. The method of claim 13, wherein
the single second thin-film portion includes a first layer having holes above the second plate-like portions, respectively, and a second layer provided on the first layer and filling the holes.

15. The method of claim 10, wherein
each of the second plate-like portions has a structure in which a plurality of material layers formed of different materials are stacked.

16. The method of claim 10, wherein
during a manufacturing process, each of the second plate-like portions is warped such that a central part of each of the second plate-like portions is away from a principal surface of the semiconductor wafer.

17. The method of claim 10, wherein
the first plate-like portion is movable in a direction perpendicular to a principal surface of the semiconductor wafer.

18. The method of claim 10, wherein
the first plate-like portion functions as an electrode of a variable capacitor.

19. The method of claim 10, wherein
the semiconductor wafer includes a plurality of shot regions, each of the shot regions including a plurality of chip regions, and
the first element and the second element unit are formed in a same chip region.

20. The method of claim 10, wherein
the semiconductor wafer includes a plurality of shot regions, each of the shot regions including a plurality of chip regions, and
the first element and the second element unit are formed in different chip regions.
